(19) United States
(12) Patent Application Publication
(10) Pub. No.: US 2023/0309362 A1
(43) Pub. Date: Sep. 28, 2023

(54) DISPLAY DEVICE AND MANUFACTURING METHOD THEREOF

(71) Applicant: SHARP KABUSHIKI KAISHA, Sakai City, Osaka (JP)

(72) Inventors: TOHRU OKABE, Sakai City, Osaka (JP); SHOJI OKAZAKI, Sakai City, Osaka (JP); SHINJI ICHIKAWA, Sakai City, Osaka (JP); HIROKI TANIYAMA, Sakai City, Osaka (JP); SHINSUKE SAIDA, Sakai City, Osaka (JP)

(21) Appl. No.: 18/009,970

(22) PCT Filed: Jun. 25, 2020
(86) PCT No.: PCT/JP2020/025080

§ 371 Date: Dec. 12, 2022

(51) Int. Cl. H10K 59/80; H10K 59/12; H10K 59/131

(52) U.S. Cl. CPC H10K 59/873; H10K 59/1201; H10K 59/131

(57) ABSTRACT

A display device, includes: a resin substrate layer; a thin-film transistor layer; a light-emitting-element layer provided on the thin-film transistor layer and including a plurality of first electrodes, a plurality of light-emitting functional layers, and a second electrode stacked on top of another in a stated order; a frame region; a terminal unit; a folding portion; a slit; a filling resin film; a plurality of routed wires; and a reinforcing resin film, wherein the reinforcing resin film is provided with a first dam wall toward the display region, the first dam wall being in contact with the reinforcing resin film and extending in the direction in which the folding portion extends, and the reinforcing resin film is provided with a second dam wall toward the terminal unit, the second dam wall being in contact with the reinforcing resin film and extending in the direction in which the folding portion extends.

### TECHNICAL FIELD

The present invention relates to a display device and a manufacturing method thereof.

### BACKGROUND ART

In recent years, light-emitting organic electroluminescence (EL) display devices using organic EL elements are drawing attention as a replacement for liquid crystal display devices. Among these organic EL display devices, a flexible organic EL display device is proposed. In the organic EL display device, such components as organic EL devices are formed on a flexible resin substrate layer. Here, the organic EL display device includes a frame region provided around a display region that displays an image. This frame region is requested to be reduced in area; that is, to be formed narrower. Then, as to the flexible organic EL display device, when the frame region is folded, and an area occupied with the frame region is reduced in plan view, wires arranged in the frame region could break.

For example, Patent Document 1 discloses a flexible display device. In the flexible display device, a bending hole is formed to partially remove each of a buffer film, a gate insulating film, and an interlayer insulating film, all of which correspond to a bending region. Thus, the bending hole keeps wires from breaking.

### CITATION LIST

### Patent Literature

[Patent Document 1] Japanese Unexamined Patent Application Publication No. 2014-232300

### SUMMARY OF INVENTION

### Technical Problems

In the flexible organic EL display device, such inorganic insulating films as a base coat film, a gate insulating film, and an interlayer insulating film are provided on a resin substrate layer. Hence, in order to reduce breaks of a plurality of routed wires arranged in the frame region, a structure is proposed as follows: The inorganic insulating films are partially removed from a portion of the frame region to be folded (a folding portion of the frame region). In the removed portion, a filling film is formed. On the filling film, the routed wires are formed. Here, the proposed structure includes: a planarization resin film provided on the plurality of routed wires to protect each of the routed wires; and a reinforcing resin film provided on the planarization resin film to reinforce the folding portion. In a mounting step, for example, the reinforcing resin film is supplied and formed, using such an apparatus as a dispenser apparatus. The reinforcing resin film spreads out, which makes it difficult to form the frame region narrower. That is why the structure has room for improvement.

In view of the above problems, the present invention is intended to form a frame region of a display device narrower even if a reinforcing resin film is provided on a routed wire of a folding portion.

### Solution to Problems

In order to achieve the above object, a display device according to the present invention includes: a resin substrate layer; a thin-film transistor layer provided on the resin substrate layer and including an inorganic insulating film; a light-emitting-element layer provided on the thin-film transistor layer and including a plurality of first electrodes, a plurality of light-emitting functional layers, and a second electrode stacked on top of another in a stated order, each of the plurality of first electrodes and each of the plurality of light-emitting functional layers corresponding to one of a plurality of sub-pixels included in a display region, and the second electrode being provided in common among the plurality of sub-pixels; a frame region provided around the display region; a terminal unit provided to an end portion of the frame region; a folding portion provided between the display region and the terminal unit to extend in a direction; a slit included in the inorganic insulating film and provided to the folding portion to extend in the direction in which the folding portion extends; a filling resin film provided to the folding portion to fill the slit; a plurality of routed wires provided on the filling resin film to extend in parallel with one another in the direction in which the folding portion extends; and a reinforcing resin film provided in the folding portion, the reinforcing resin film being shaped into a strip, being provided on the plurality of routed wires, and extending in the direction in which the folding portion extends, wherein the reinforcing resin film is provided with a first dam wall toward the display region, the first dam wall being in contact with the reinforcing resin film and extending in the direction in which the folding portion extends, and the reinforcing resin film is provided with a second dam wall toward the terminal unit, the second dam wall being in contact with the reinforcing resin film and extending in the direction in which the folding portion extends.

Moreover, a method of manufacturing a display device according to the present invention includes: a thin-film transistor layer forming step of forming, on a resin substrate layer, a thin-film transistor layer including an inorganic insulating film; a light-emitting-element layer forming step of forming, on the thin-film transistor layer, a light-emitting element layer including a plurality of first electrodes, a plurality of light-emitting functional layers, and a second electrode stacked on top of another in a stated order, each of the plurality of first electrodes and each of the plurality of light-emitting functional layers corresponding to one of a plurality of sub-pixels included in a display region, and the second electrode being provided in common among the plurality of sub-pixels; and a sealing film forming step of forming, on the light-emitting element layer, a sealing film including a first inorganic sealing film, an organic sealing film, and a second inorganic sealing film stacked on top of another in a stated order, the display device including: a frame region provided around the display region; a terminal unit provided to an end portion of the frame region; a folding portion provided between the display region and the terminal unit to extend in a direction; a first frame dam wall provided in the frame region, surrounding the display region, and shaped into a frame to overlap with a peripheral end portion of the organic sealing film; and a second frame dam wall shaped into a frame and provided around the first frame dam wall, wherein the thin-film transistor layer forming step includes: a slit forming step of forming a slit provided to the folding portion to extend in the direction in which the folding portion extends; a filling resin film forming step of forming a filling resin film to fill the slit; and a routed wire forming step of forming a plurality of routed wires provided on the filling resin film to extend in parallel with one another in the direction in which the folding portion extends, the thin-film transistor layer forming step and the light-emitting-element layer forming step include a folding dam wall forming step of forming a folding dam wall shaped into a rectangular frame having a pair of long sides extending in the direction in which the folding portion extends, the long sides sandwiching the folding portion, and when the organic sealing film is formed in an interior of the first frame dam wall, the sealing film forming step forms a reinforcing resin film on the plurality of routed wires behind the folding dam wall, the reinforcing resin film being shaped into a strip.

### Advantageous Effects of Invention

According to the present invention, the reinforcing resin film is provided with the first dam wall toward the display region. The first dam wall is in contact with the reinforcing resin film, and extends in the direction in which the folding portion extends. Moreover, the reinforcing resin film is provided with the second dam wall toward the terminal unit. The second dam wall is in contact with the reinforcing resin film, and extends in the direction in which the folding portion extends. Such features make it possible to form the frame region of the display device narrower even if the reinforcing resin film is provided on the routed wires of the folding portion.

### BRIEF DESCRIPTION OF DRAWINGS

FIG. 1 is a plan view of a schematic configuration of an organic EL display device according to a first embodiment of the present invention.

FIG. 2 is a plan view of a display region of the organic EL display device according to the first embodiment of the present invention.

FIG. 3 is a cross-sectional view of the organic EL display device, taken from line III-III in FIG. 1.

FIG. 4 is an equivalent circuit diagram illustrating a thin-film transistor layer included in the organic EL display device according to the first embodiment of the present invention.

FIG. 5 is a cross-sectional view of an organic EL layer included in the organic EL display device according to the first embodiment of the present invention.

FIG. 6 is a cross-sectional view of a frame region included in the organic EL display device, taken from line VI-VI in FIG. 1.

FIG. 7 is a cross-sectional view of the frame region included in the organic EL display device, taken from line VII-VII in FIG. 1.

FIG. 8 is a cross-sectional view of a frame region in Modification 1 of the organic EL display device according to the first embodiment of the present invention. FIG. 8 corresponds to FIG. 7.

FIG. 9 is a plan view of a schematic configuration in Modification 2 of the organic EL display device according to the first embodiment of the present invention. FIG. 9 corresponds to FIG. 1.

FIG. 10 is a cross-sectional view of the frame region of the organic EL display device, taken from line X-X in FIG. 9. FIG. 10 corresponds to FIG. 7.

FIG. 11 is a plan view of a schematic configuration in Modification 3 of the organic EL display device according to the first embodiment of the present invention. FIG. 11 corresponds to FIG. 1.

FIG. 12 is a cross-sectional view of an organic EL display device according to a second embodiment of the present invention. FIG. 12 corresponds to FIG. 3.

FIG. 13 is a cross-sectional view of a frame region of the organic EL display device according to the second embodiment of the present invention. FIG. 13 corresponds to FIG. 6.

FIG. 14 is a cross-sectional view of the frame region of the organic EL display device according to the second embodiment of the present invention. FIG. 14 corresponds to FIG. 7.

### DESCRIPTION OF EMBODIMENTS

Described below in derail are embodiments of the present invention, with reference to the drawings. Note that the present invention shall not be limited to the embodiments below.

### First Embodiment

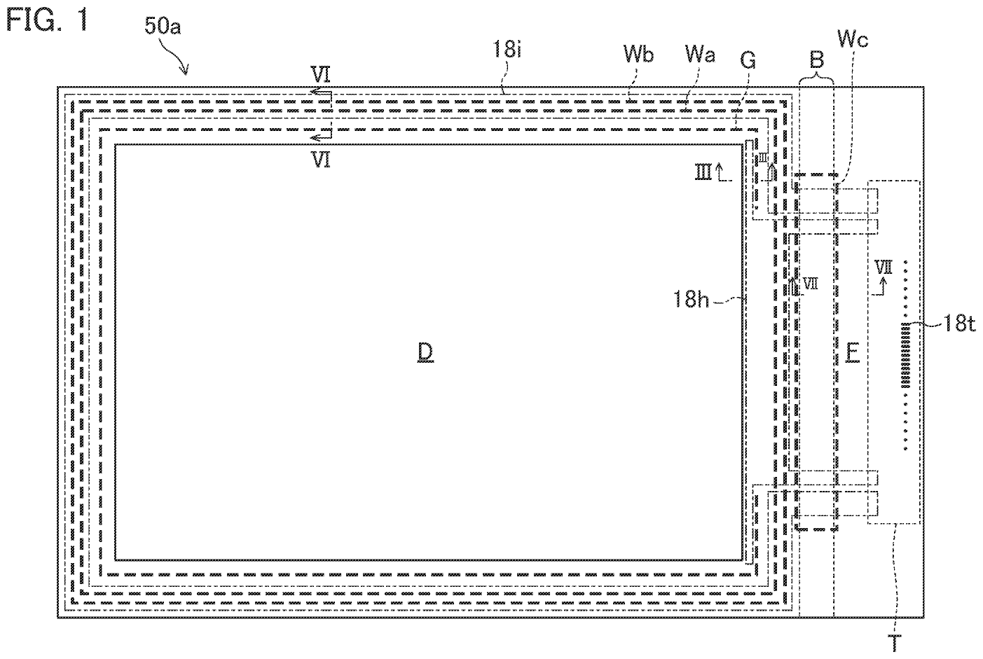

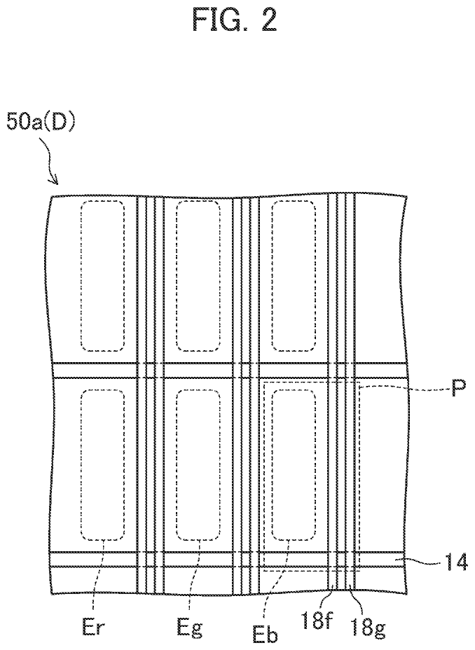

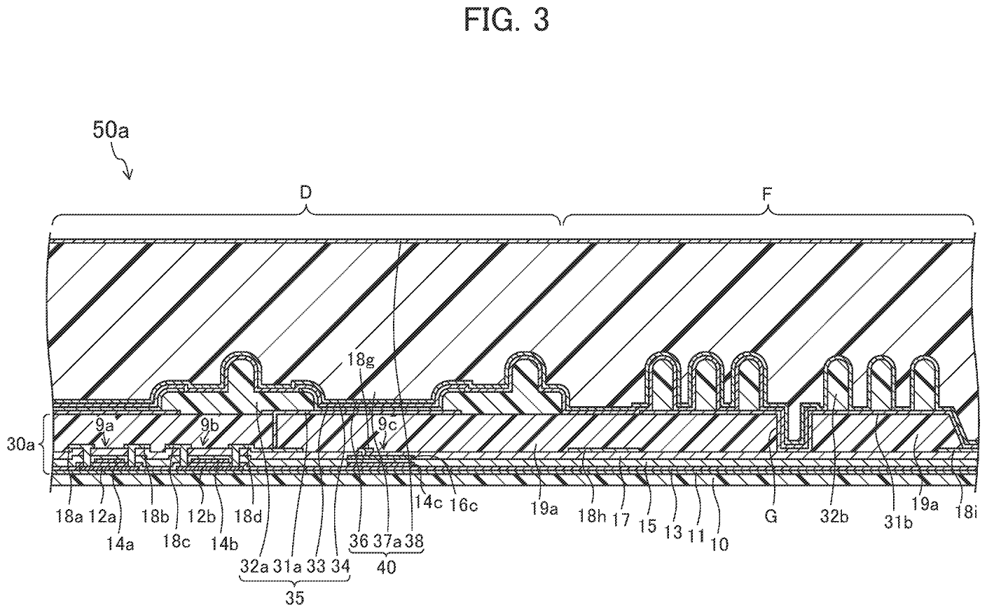

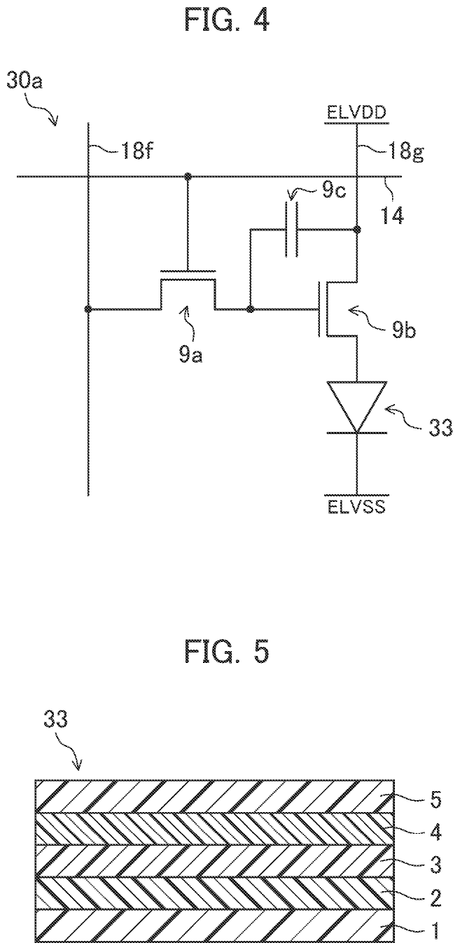

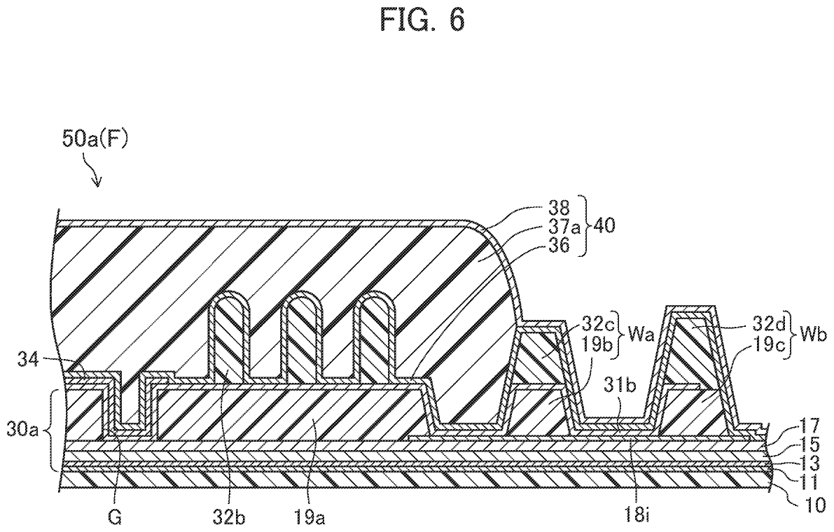

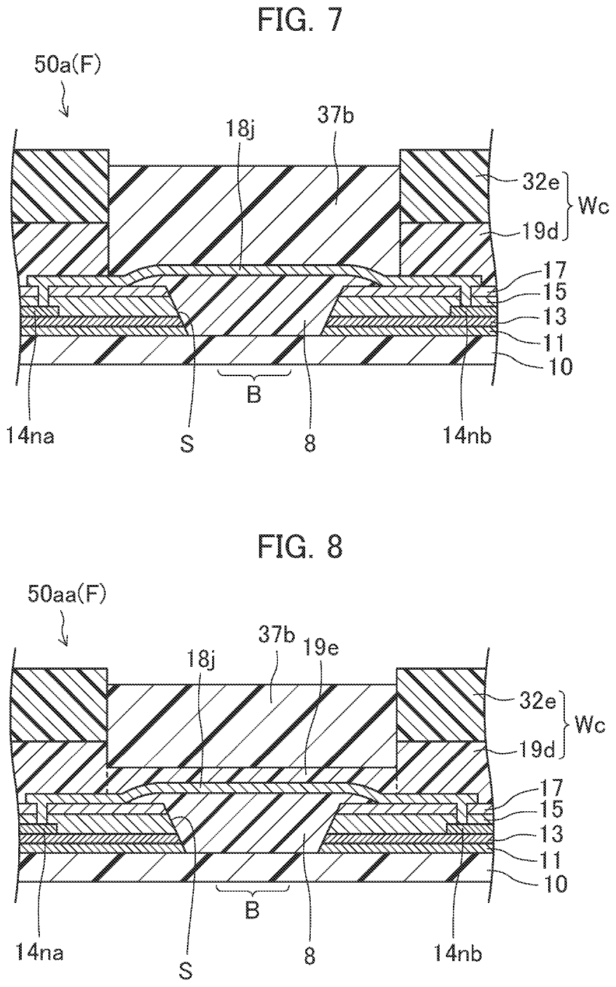

FIGS. 1 to 11 illustrate a first embodiment of a display device and a method of manufacturing the display device according to the present invention. The embodiments below exemplify an organic EL display device including an organic EL element, as a display device including a light-emitting element. FIG. 1 is a plan view of a schematic configuration of an organic EL display device 50a according to this embodiment. FIG. 2 is a plan view of a display region D of the organic EL display device 50a. FIG. 3 is a cross-sectional view of the organic EL display device 50a, taken from line III-HI in FIG. 1. FIG. 4 is an equivalent circuit diagram illustrating a thin-film transistor layer 30a included in the organic EL display device 50a. FIG. 5 is a cross-sectional view of an organic EL layer 33 included in the organic EL display device 50a. FIG. 6 is a cross-sectional view of a frame region F included in the organic EL display device 50a, taken from line VI-VI in FIG. 1. FIG. 7 is a cross-sectional view of the frame region F included in the organic EL display device 50a, taken from line VII-VII in FIG. 1.

As illustrated in FIG. 1, the organic EL display device 50a includes, for example: the display region D shaped into a rectangle and displaying an image; and the frame region F shaped into a rectangular frame, and provided around the display region D. Note that, in this embodiment, the display region D is, for example, rectangular. Examples of the rectangle include such substantial rectangles as a rectangle having arc-like sides, a rectangle having rounded corners, and a rectangle having partially notched sides.

As illustrated in FIG. 2, the display region D includes a plurality of sub-pixels P arranged in a matrix. In the display region D, as illustrated in FIG. 2, for example, the sub pixels P having red light-emitting areas Er for presenting red, the sub-pixels P having green light-emitting areas Eg for presenting green, and the sub pixels P having blue light-emitting areas Eb for presenting blue are provided next to each other. Note that, in the display region D, for example, neighboring three of the sub-pixels P constitute one pixel, and each of the three sub-pixels P has one of a red light-emitting area Er, a green light-emitting area Eg, and a blue light-emitting area Eb.

In FIG. 1, the frame region F has a right end portion provided with a terminal T extending in a direction (the vertical direction in the drawing). Moreover, as illustrated in FIG. 1, the frame region F includes a folding portion B between the display region D and the terminal T. The folding portion B, extending in a direction (the vertical direction in the drawing), is foldable around a folding axis in the vertical direction at an angle of, for example, 180° (foldable in a U-shape). Furthermore, as will be described later, the terminal unit T includes a plurality of terminals 18t arranged in the direction in which the terminal unit T extends. In addition, in the frame region F, a planarization resin film 19a to be described later is provided with a trench G shaped into a substantial C-shape in plan view and penetrating the planarization resin film 19a as illustrated in FIGS. 1, 3, and 6. Here, as illustrated in FIG. 1, the trench G is laid into a substantial C-shape to open toward the terminal unit T in in plan view.

As illustrated in FIGS. 3 and 6, the organic EL display device 50a includes: a resin substrate layer 10; a thin-film transistor (hereinafter also referred to as “TFT”) layer 30a provided on the resin substrate layer 10; an organic-EL-element layer 35 provided on the TFT layer 30a and serving as a light-emitting-element layer; and a sealing film 40 provided on the organic-EL-element layer 35.

The resin substrate layer 10 is made of, for example, polyimide resin.

As illustrated in FIG. 3, the TFT layer 30a includes: a base coat film 11 provided on the resin substrate layer 10; a plurality of first TFTs 9a, a plurality of second TFTs 9b, and a plurality of capacitors 9c provided on the base coat film 11; and the planarization resin film 19a provided on each of the first TFTs 9a, each of the second TFTs 9b, and each of the capacitors 9c. Here, as illustrated in FIGS. 2 and 4, the TFT layer 30a includes a plurality of gate lines 14 horizontally extending in parallel with one another in the drawings. Moreover, as illustrated in FIGS. 2 and 4, the TFT layer 30a includes a plurality of source lines 18f vertically extending in parallel with one another in the drawings. Furthermore, as illustrated in FIGS. 2 and 4, the TFT layer 30a includes a plurality of power source lines 18g vertically extending in parallel with one another in the drawings. Then, as illustrated in FIG. 2, the power source lines 18g and the source lines 18f are provided next to each other. Moreover, in the TFT layer 30a, as illustrated in FIG. 4, each of the sub pixels P includes a first TFT 9a, a second TFT 9b, and a capacitor 9c.

As illustrated in FIG. 4, in each sub-pixel P, the first TFT 9a is electrically connected to the corresponding gate line 14 and source line 18f. The first TFT 9a illustrated in FIG. 3 includes: a semiconductor layer 12a; a gate insulating film 13; a gate electrode 14a; a first interlayer insulating film 15; a second interlayer insulating film 17; and a source electrode 18a and a drain electrode 18b, all of which are provided above the base coat film 11 in the stated order. The semiconductor layer 12a illustrated in FIG. 3 is, for example, made of low-temperature-polysilicon film and shaped into an island. The semiconductor layer 12a includes a channel region, a source region, and a drain region. The gate insulating film 13 illustrated in FIG. 3 is provided to cover the semiconductor layer 12a. The gate electrode 14a illustrated in FIG. 3 is provided on the gate insulating film 13 to overlap the channel region of the semiconductor layer 12a. The first interlayer insulating film 15 and the second interlayer insulating film 17 illustrated in FIG. 3 are provided in the stated order to cover the gate electrode 14a. The source electrode 18a and the drain electrode 18b illustrated in FIG. 3 are spaced apart from each other on the second interlayer insulating film 17. As illustrated in FIG. 3, the source electrode 18a and the drain electrode 18b are respectively and electrically connected to the source region and the drain region of the semiconductor layer 12a through contact holes each formed in a multilayer film including the gate insulating film 13, the first interlayer insulating film 15, and the second interlayer insulating film 17. Note that each of the base coat film 11, the gate insulating film 13, the first interlayer insulating film 15, and the second interlayer insulating film 17 is, for example, a monolayer inorganic insulating film made of such a material as silicon nitride, silicon oxide, or silicon oxide nitride. Alternatively, each of the films is a multilayer inorganic insulating film made of these materials.

As illustrated in FIG. 4, in each sub-pixel P, the second TFT 9b is electrically connected to the corresponding first TFT 9a and power source line 18g. The second TFT 9b illustrated in FIG. 3 includes: a semiconductor layer 12b; the gate insulating film 13, a gate electrode 14b; the first interlayer insulating film 15; the second interlayer insulating film 17; and a source electrode 18c and a drain electrode 18d, all of which are provided above the base coat film 11 in the stated order. The semiconductor layer 12b illustrated in FIG. 3 is, for example, made of low-temperature-polysilicon film and shaped into an island. The semiconductor layer 12b includes a channel region, a source region, and a drain region. The gate insulating film 13 illustrated in FIG. 3 is provided to cover the semiconductor layer 12b. The gate electrode 14b illustrated in FIG. 3 is provided on the gate insulating film 13 to overlap the channel region of the semiconductor layer 12b. The first interlayer insulating film 15 and the second interlayer insulating film 17 illustrated in FIG. 3 are provided in the stated order to cover the gate electrode 14b. The source electrode 18c and the drain electrode 18d illustrated in FIG. 3 are spaced apart from each other on the second interlayer insulating film 17. As illustrated in FIG. 3, the source electrode 18c and the drain electrode 18d are respectively and electrically connected to the source region and the drain region of the semiconductor layer 12b through contact holes each formed in a multilayer film including the gate insulating film 13, the first interlayer insulating film 15, and the second interlayer insulating film 17.

Note that, as an example, the first TFTs 9a and the second TFTs 9b in this embodiment are top gate TFTs. Alternatively, the first TFTs 9a and the second TFTs 9b may be bottom gate TFTs.

As illustrated in FIG. 4, in each sub-pixel P, the capacitor 9c is electrically connected to the corresponding first TFT 9a and power source line 18g. The capacitor 9c illustrated in FIG. 3 includes: a lower conductive layer 14c formed of the same material as, and in the same layer as, the gate lines 14 and the gate electrodes 14a and 14b are; the first interlayer insulating film 15 provided to cover the lower conductive layer 14c; and an upper conductive layer 16c provided on the first interlayer insulating film 15 to overlap the lower conductive layer 14c. Note that the upper conductive layer 16c illustrated in FIG. 3 is electrically connected to the power source line 18g through a contact hole formed in the second interlayer insulating film 17.

The planarization resin film 19a has a flat surface in the display region D. The planarization resin film 19a is made of such an organic resin material as, for example, polyimide resin, acrylic resin, or polysiloxane resin.

As illustrated in FIG. 3, the organic-EL-element layer 35 includes: a plurality of first electrodes 31a; an edge cover 32a; a plurality of organic EL layers 33; and a second electrode 34, all of which are provided above the TFT layer 30 in the stated order.

The plurality of first electrodes 31a illustrated in FIG. 3 are provided on the planarization film 19a in a matrix, so that each of the first electrodes 31a corresponds to one of the plurality of sub-pixels P. Here, as illustrated in FIG. 3, each of the first electrodes 31a is electrically connected to the drain electrode 18d of a corresponding one of the second TFTs 9b through a contact hole formed in the planarization resin film 19a. Moreover, the first electrodes 31a are provided as anodes, and capable of injecting holes into the organic EL layers 33. Furthermore, preferably, each of the first electrodes 31a is formed of a material having a high work function in order to improve efficiency in injecting the holes into the organic EL layers 33. Exemplary materials of the first electrodes 31a include such metal materials as, for example, silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Moreover, the exemplary materials of the first electrodes 31a may also include, for example, an alloy of astatine (At)/astatine dioxide (AtO₂). Furthermore, exemplary materials of the first electrodes 31a may include such conductive oxides as, for example, tin oxide (SnO), zinc oxide (ZnO), indium tin oxide (ITO), and indium zinc oxide (IZO). Each of the first electrodes 31a may be a multilayer including two or more layers made of the above materials. Note that exemplary compound materials having a large work function include indium tin oxide (ITO) and indium zinc oxide (IZO).

The edge cover 32a illustrated in FIG. 3 is provided in a grid in common among the plurality of sub-pixels P to cover a peripheral end portion of each of the first electrodes 31a. Here, exemplary materials of the edge cover 32a include such organic resin materials as polyimide resin, acrylic resin, and polysiloxane resin.

The plurality of organic EL layers 33 illustrated in FIG. 3 are disposed above the respective first electrodes 31a and provided in a matrix, so that each of the organic EL layers 33 corresponds to one of the sub-pixels P. The organic EL layers 33 serve as light-emitting functional layers. Here, as illustrated in FIG. 5, each of the organic EL layers 33 includes: a hole-injection layer 1; a hole-transport layer 2; a light-emitting layer 3; an electron-transport layer 4; and an electron-injection layer 5, all of which are provided above the first electrode 31a in the stated order.

The hole injection layer 1, also referred to as an anode buffer layer, is capable of approximating the energy levels of the first electrode 31a and the organic EL layer 33, and of increasing efficiency in injection of the holes from the first electrode 31a to the organic EL layer 33. Exemplary materials of the hole injection layer 1 may include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole-transport layer 2 is capable of improving efficiency in transporting the holes from the first electrode 31a to the organic EL layer 33. Here, exemplary materials of the hole transport-layer 2 may include a porphyrin derivative, an aromatic tertiary amine compound, a styryl amine derivative, polyvinylcarbazole, poly-p-phenylene vinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted chalcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, and zinc selenide.

The light-emitting layer 3 is a region into which the holes and the electrons are injected from the first electrode 31a and the second electrode 34, and in which the holes and the electrons recombine together, when a voltage is applied by the first electrode 31a and the second electrode 34. Here, the light-emitting layer 3 is formed of a material with high light emission efficiency. Exemplary materials of the light-emitting layer 3 may include a metal oxinoid compound [an 8-hydroxyquinoline metal complex], a naphthalene derivative, an anthracene derivative, a diphenylethylene derivative, a vinylacetone derivative, a triphenylamine derivative, a butadiene derivative, a coumarin derivative, a benzoxazole derivative, an oxadiazole derivative, an oxazole derivative, a benzimidazole derivative, a thiadiazole derivative, a benzothiazole derivative, a styryl derivative, a styrylamine derivative, a bisstyrylbenzene derivative, a trisstyrylbenzene derivative, a perylene derivative, a perinone derivative, an aminopyrene derivative, a pyridine derivative, a rodamine derivative, an acridine derivative, phenoxazone, a quinacridone derivative, rubrene, poly-P-phenylene vinylene, and polysilane.

The electron-transport layer 4 is capable of efficiently transporting the electrons to the light-emitting layer 3. Exemplary materials of the electron-transport layer 4 include, as organic compounds, for example, an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound.

The electron-injection layer 5 is capable of approximating the energy levels of the second electrode 34 and the organic EL layer 33, and increasing efficiency in injection of the electrons from the second electrode 34 to the organic EL layer 33. Such a feature makes it possible to decrease a drive voltage of the organic EL element. Note that the electron-injection layer 5 may also be referred to as a cathode buffer layer. Exemplary materials of the electron-injection layer 5 may include: such inorganic alkaline compounds as lithium fluoride (LiF), magnesium fluoride magnesium fluoride (MgF₂), calcium fluoride (CaF₂), strontium fluoride (SrF₂), and barium fluoride (BaF₂); aluminum oxide (Al₂O₃); and strontium oxide (SrO).

The second electrode 34 is provided on the plurality of organic EL layers 33 in common among the plurality of sub-pixels P. That is, as illustrated in FIG. 3, the second electrode 34 is provided to cover each of the organic EL layers 33 and the edge cover 32a. Moreover, the second electrode 34 is provided as a cathode, and capable of injecting the electrons into the organic EL layers 33. Furthermore, preferably, the second electrode 34 is made of a material having a low work function in order to improve efficiency in injection of the electrons into the organic EL layers 33. Here, exemplary materials of the second electrodes 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Moreover, the second electrode 34 may also be formed of an alloy of, for example, magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), and lithium fluoride (LiF)/calcium (Ca)/aluminum (Al). Furthermore, the second electrode 34 may also be formed of such conductive oxides as, for example, tin oxide (SnO), zinc oxide (ZnO), indium tin oxide (ITO), and indium zinc oxide (IZO). In addition, the second electrode 34 may be a multilayer including two or more layers made of the above materials. Note that exemplary materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and fluoride (LiF)/calcium (Ca)/aluminum (Al).

The sealing film 40 illustrated in FIG. 3 is provided to cover the second electrode 34. The sealing film 40 includes: a first inorganic sealing film 36; an organic sealing film 37a; and a second inorganic sealing film 38, all of which are stacked on top of another above the second electrode 34 in the stated order in order to protect the organic EL layers 33 of the organic-EL-element layer 35 from water and oxygen. Here, the first inorganic sealing film 36 and the second inorganic sealing film 38 are made of such inorganic insulating films as, for example, silicon nitride films, silicon oxide films, or silicon oxide nitride films. Moreover, exemplary materials of the organic film 37a include such organic materials as acrylic resin, epoxy resin, silicone resin, polyuria resin, parylene resin, polyimide resin, and polyamide resin.

Furthermore, the organic EL display device 50a illustrated in FIG. 1 includes in the frame region F: a first frame dam wall Wa shaped into a frame and provided outside the trench G to surround the display region D; and a second frame dam wall Wb shaped into a frame and provided around the first frame dam wall Wa.

The first frame dam wall Wa, as illustrated in FIG. 6, includes: a lower resin layer 19b formed of the same material as, and in the same layer as, the planarization resin layer 19a is; and an upper resin layer 32c formed of the same material as, and in the same layer as, the edge cover 32a, and provided above the lower resin layer 19b through a connection wire 31b to be described later. Here, the connection wire 31b is formed of the same material as, and in the same layer as, the first electrodes 31a are. Note that the first frame dam wall Wa is provided to overlap with an outer peripheral end portion of the organic sealing film 37a in the sealing film 40, in order to reduce spread of ink that forms the organic sealing film 37a.

The second frame dam wall Wb, as illustrated in FIG. 6, includes: a lower resin layer 19c formed of the same material as, and in the same layer as, the planarization resin layer 19a is; and an upper resin layer 32d formed of the same material as, and in the same layer as, the edge cover 32a is, and provided above the lower resin layer 19c through the connection wire 31b.

Moreover, as illustrated in FIG. 1, the organic EL display device 50a includes a first frame wire 18h extending widely in a portion of the frame region F where the trench G is open. The first frame wire 18h has: opposing ends, toward the display region D, extending linearly behind the trench G along the right side of the display region D in the drawing; and opposing ends, across from the display region D, extending toward the terminal unit T. Here, the first frame wire 18h is electrically connected to the power source lines 18g in the frame region F toward the display region D. The first frame wire 18h receives a high power-source voltage (ELVDD) at the terminal unit T. Note that the first frame wire 18h, and a second frame wire 18i and a routed wire 18j to be described later, are formed of the same material as, and in the same layer as, the source electrodes 18a and 18c, the drain electrodes 18c and 18d, the source lines 18f, and the power source lines 18g are.

Furthermore, as illustrated in FIG. 1, the organic EL display device 50a includes the second frame wire 18i shaped into a substantial C-shape and laid in the frame region F outside the trench G. The second frame wire 18i has opposing ends extending toward the terminal unit T. Here, the second frame wire 18i is, as illustrated in FIG. 6, electrically connected to the second electrode 34 of the display region D through the connection wire 31b provided in the trench G. The second frame wire 18i receives a low power-source voltage (ELVSS) at the terminal unit T.

In addition, as illustrated in FIGS. 3 and 6, the organic EL display device 50a includes, in the frame region F, a plurality of peripheral photo spacers 32b each shaped into an island and provided to extend upwards at opposing edge portions of the trench G. Here, the peripheral photo spacers 32b are formed of the same material as, and in the same layer as, the edge cover 32a is.

Moreover, as illustrated in FIG. 7, the organic EL display device 50a includes in a folding portion B of the frame region F: a filling resin film 8 provided to fill a slit S formed in a multilayer film of the base coat film 11, the gate insulating film 13, the first interlayer insulating film 15, and the second interlayer insulating film 17; a plurality of the routed wires 18j provided on the filling resin film 8 and the second interlayer insulating film 17; and a reinforcing resin film 37b provided to cover an intermediate portion of each of the routed wires 18j.

As illustrated in FIG. 7, the slit S is provided to penetrate the base coat film 11, the gate insulating film 13, the first interlayer insulating film 15, and the second interlayer insulating film 17, and shaped into a groove to stretch in a direction in which the folding portion B extend in order to expose an upper surface of the resin substrate layer 10.

The filling resin film 8 is made of such an organic resin material as, for example, polyimide resin, acrylic resin, or polysiloxane resin.

The plurality of routed wires 18j are provided to extend in parallel with one another in a direction perpendicular to the direction in which the folding portion B extends. Here, as illustrated in FIG. 7, each of the routed wires 18j has opposing ends. One of the opposing ends is electrically connected to a first gate conductive layer 14na and another one of the opposing ends is electrically connected to a second gate conductive layer 14nb, through respective contact holes formed in a multilayer film of the first interlayer insulating film 15 and the second interlayer insulating film 17. Note that the first gate conductive layer 14na is formed of the same material as, and in the same layer as, the gate lines 14 and the gate electrodes 14a and 14b are. The first gate conductive layer 14na is electrically connected to a display wire (such as the source line 18f) disposed in the display region D. Moreover, the second gate conductive layer 14nb is formed of the same material as, and in the same layer as, the gate lines 14 and the gate electrodes 14a and 14b are. The second gate conductive layer 14nb is electrically connected to a terminal 18t of the terminal unit T.

The reinforcing resin film 37b illustrated in FIG. 7 is provided in the folding portion B. The reinforcing resin film 37b is shaped into a strip, is provided on intermediate portions of the plurality of routed wires 18j, and extends in the direction in which the folding portion B extends. Here, the reinforcing resin film 37b is formed of the same material as, and in the same layer as, the organic sealing film 37a is. Moreover, as illustrated in FIGS. 1 and 7, the reinforcing resin film 37b is surrounded with a folding dam wall We shaped into a single frame.

The folding dam wall Wc illustrated in FIG. 7 includes: a lower resin layer 19d formed of the same material as, and in the same layer as, the planarization resin layer 19a is; and an upper resin layer 32e stacked on the lower resin layer 19d and formed of the same material as, and in the same layer as, the edge cover 32a is. The folding dam wall We is in contact with the reinforcing resin layer 37b.

Note that this embodiment exemplifies the organic EL display device 50a including the reinforcing resin film 37b on each of the routed wires 18j. Alternatively, this embodiment may present an organic EL display device 50aa including a base resin film 19e provided between each of the routed wires 18j and the reinforcing resin film 37b. Here, FIG. 8 is a cross-sectional view of the frame region F of the organic EL display device 50aa; that is, Modification 1 of the organic EL display device 50a.

As illustrated in FIG. 8, in the organic EL display device 50aa, the base resin film 19e is provided in the folding portion B. The base resin film 19e is shaped into a strip formed on intermediate portions of the plurality of routed wires 18j and extending in the direction in which the folding portion B extends. The reinforcing resin film 37b is shaped into a strip formed on the base resin film 19e and extending in the direction in which the folding portion extends. Here, the base resin film 19e in FIG. 8 is made of the same material as, and in the same layer as, the planarization resin film 19a is. The base resin film 19e is formed thinner than the planarization resin film 19a, and provided integrally with the lower resin film 19d. Note that, when the planarization resin film 19a and the lower resin film 19d are formed of, for example, photosensitive resin, the base resin film 19e may be formed thinner than the lower resin film 19d by half exposure using, for example, a gray-tone mask or a half-tone mask. As to this organic EL display device 50aa, each of the routed wires 18j is covered with the lower resin layer 19d and the base resin film 19e. Hence, each of the routed wires 18j is less likely to be etched sideways with a developing solution to be used when the planarization resin film 19a is formed, an etching solution to be used when the first electrodes 31a are formed, and a developing solution to be used when the edge cover 32a is formed. As a result, an increase in wiring resistance can be reduced of each of the routed wires 18j. Moreover, as to this organic EL display device 50aa, the surface on which the reinforcing resin film 37b is formed is flat; that is, the surface of the base resin film 19e is flat. Such a feature allows better control of the thickness of the reinforcing resin film 37b to be formed by ink-jet printing. Furthermore, as to this organic EL display device 50aa, the base resin film 19e and the reinforcing resin film 37b are both made of a resin material. Such a feature can provide the reinforcing resin film 37b with higher adhesiveness in the organic display device 50aa than in the organic EL display device 50a.

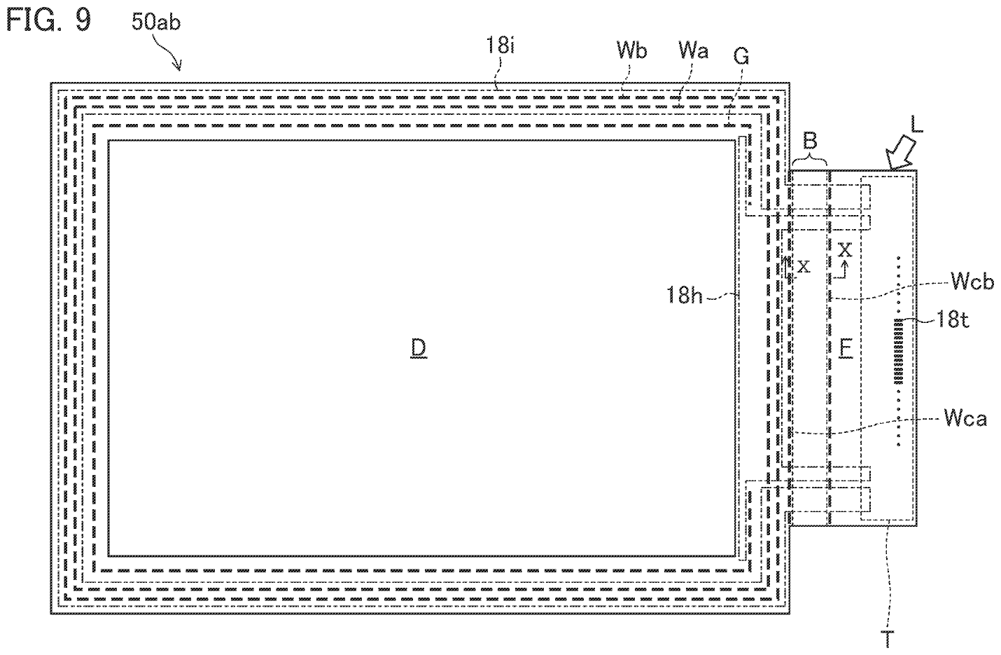

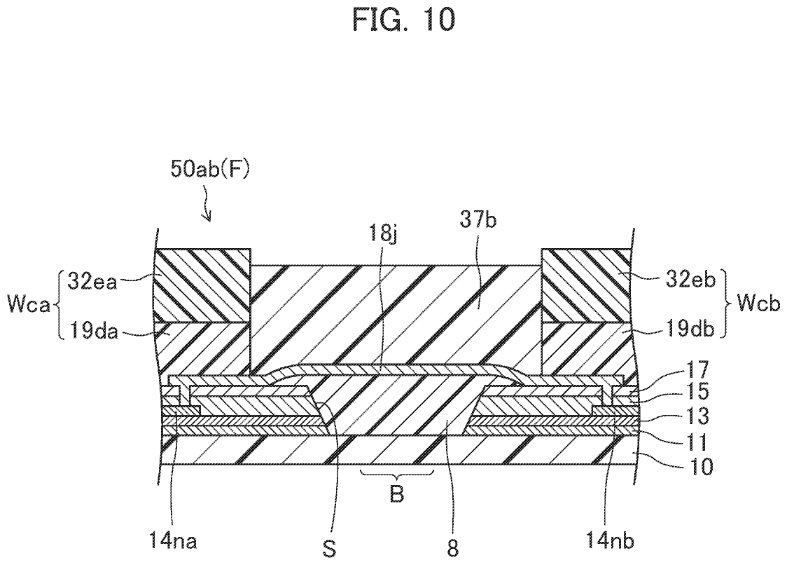

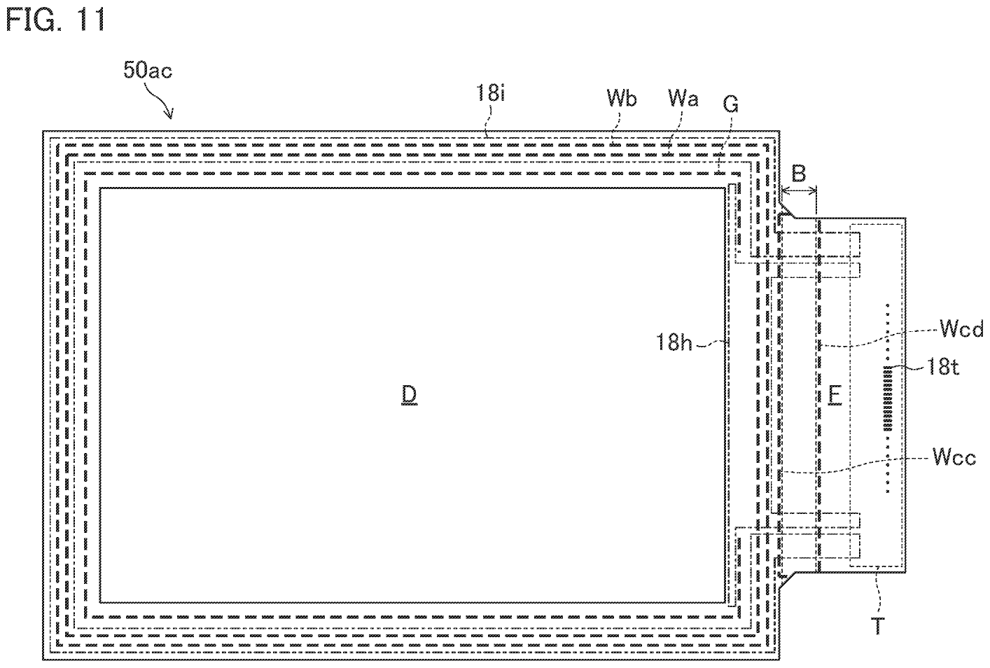

In addition, this embodiment exemplifies the organic EL display device 50a including the folding dam wall We shaped into a frame. Alternatively, this embodiment may present: an organic EL display device 50ab including a first dam wall Wca and a second dam wall Wcb extending in parallel with each other; and an organic EL display device 50ac including a first dam wall Wcc and a second dam wall Wcd extending in parallel with each other. Here, FIG. 9 is a plan view of a schematic configuration of the organic EL display device 50ab; that is, Modification 2 of the organic EL display device 50a. FIG. 9 corresponds to FIG. 1. Moreover, FIG. 10 is a cross-sectional view of the frame region F of the organic EL display device 50ab, taken from line X-X in FIG. 9. FIG. 10 corresponds to FIG. 7. Furthermore, FIG. 11 is a plan view of a schematic configuration of the organic EL display device 50ac; that is, Modification 3 of the organic EL display device 50a. FIG. 11 corresponds to FIG. 1.

The organic EL display device 50ab is the organic EL display device 50a with an upper-right corner portion and a lower-right corner portion in FIG. 1 rectangularly cut off. In a method of manufacturing the organic EL display device 50a to be described later, a laser cutting step is carried out after a sealing film forming step. In the laser cutting step, as illustrated in FIG. 9, a laser beam L is emitted to the upper-right corner portion and the lower-right corner portion of the organic EL display device 50a in FIG. 1. The laser beam L scans the corner portions in an L-shape to cut the resin substrate layer 10. This organic EL display device 50ab is the organic EL display device 50a including the folding dam wall Wc, and a pair of the short side portions of the folding dam wall Wc is removed. Hence, the organic EL display device 50ab includes, as illustrated in FIGS. 9 and 10: the first dam wall Wca shaped into a bar (shaped linearly) extending in the direction in which the folding portion B extends, and provided in contact with the reinforcing resin film 37b toward the display region D; and the second dam wall Wcb shaped into a bar (shaped linearly) extending in the direction in which the folding portion B extends, and provided in contact with the reinforcing resin film 37b toward the terminal unit T.

The organic EL display device 50ac is the organic EL display device 50a with an upper-right corner portion and a lower-right corner portion in FIG. 1 cut off substantially rectangularly while one each corner of the upper-right corner portion and the lower-right corner portion is chamfered. In a method of manufacturing the organic EL display device 50a to be described later, a laser cutting step is carried out after a sealing film forming step. In the laser cutting step, the laser beam L is emitted to the upper-right corner portion and the lower-right corner portion of the organic EL display device 50a in FIG. 1. The laser beam L scans the corner portions in a substantial L-shape to cut the resin substrate layer 10. This organic EL display device 50ac is the organic EL display device 50a including the folding dam wall Wc, and a portion, toward the terminal unit T, of a pair of the short sides of the folding dam wall Wc is removed. Hence, the organic EL display device 50ac includes, as illustrated in FIG. 11: the first dam wall Wcc shaped into a substantial bar (shaped substantially linearly) extending in the direction in which the folding portion B extends, and provided in contact with the reinforcing resin film 37b (see FIG. 10) toward the display region D; and the second dam wall Wed shaped into a substantial bar (shaped substantially linearly) extending in the direction in which the folding portion B extends, and provided in contact with the reinforcing resin film 37b toward the terminal unit T. Note that, as illustrated in FIG. 11, the first dam wall Wcc is shaped into a substantial bar (shaped substantially linearly) whose opposing end portions are each shaped into an L-shape.

The above organic EL display device 50a displays an image as follows: In each sub-pixel P, a gate signal is input through the gate line 14 to the first TFT 9a. The first TFT 9a turns ON. Through the source line 18f, a data signal is written in the gate electrode 14b of the second TFT 9b and the capacitor 9c. In accordance with a gate voltage of the second TFT 9b, a current is supplied from the power source line 18g to the organic EL layer 33. The supplied current allows the light-emitting layer 3 of the organic EL layer 33 to emit light and display the image. Note that, in the organic EL display device 50a, even if the first TFT 9a turns OFF, the gate voltage of the second TFT 9b is held in the capacitor 9c. Hence, the light-emitting layer 3 keeps emitting light until a gate signal of the next frame is input.

Described next is a method of manufacturing the organic EL display device 50a of this embodiment. Here, the method of manufacturing the organic EL display device 50a of this embodiment includes: a TFT layer forming step, an organic-EL-element layer forming step, and a sealing film forming step.

TFT Layer Forming Step (Thin-Film Transistor Layer Forming Step)

First, on the resin substrate layer 10 formed on, for example, a glass substrate, such an inorganic insulating film (a thickness of approximately 1000 nm) as a silicon oxide film is deposited by, for example, plasma chemical vapor deposition (CVD) to form the base coat film 11.

Then, throughout the substrate on which the base coat film 11 is formed, for example, an amorphous silicon film (a thickness of approximately 50 nm) is deposited by the plasma CVD. The amorphous silicon film is crystalized by such a technique as laser annealing to form a semiconductor film of a polysilicon film. After that, the semiconductor film is patterned to form such a layer as the semiconductor layer 12a.

After that, throughout the substrate on which such a layer as the semiconductor layer 12a is formed, such an inorganic insulating film (approximately 100 nm) as an silicon oxide film is deposited by, for example, the plasma CVD to form the gate insulating film 13 to cover such a layer as the semiconductor layer 12a.

Moreover, throughout the substrate on which the gate insulating film 13 is formed, such films as an aluminum film (a thickness of approximately 350 nm) and a molybdenum nitride film (a thickness of approximately 50 nm) are sequentially deposited by, for example, sputtering. After that, the metal multilayer film of these metals is patterned to form such lines as the gate lines 14.

Then, using such lines as the gate lines 14 as a mask, such a layer as the semiconductor layer 12a is doped with impurity ions. Hence, such a layer as the semiconductor layer 12a is provided with a channel region, a source region, and a drain region.

After that, throughout the substrate including such a layer as the semiconductor layer 12a provided with the channel region, the source region, and the drain region, such an inorganic insulating film (a thickness of approximately 100 nm) as an silicon oxide film is deposited by, for example, the plasma CVD to form the first interlayer insulating film 15.

Moreover, throughout the substrate on which the first interlayer insulating film 15 is formed, such films as an aluminum film (a thickness of approximately 350 nm) and a molybdenum nitride film (a thickness of approximately 50 nm) are sequentially deposited by, for example, sputtering. After that, the metal multilayer film of these metals is patterned to form such a layer as the upper conductive layer 16c.

Then, throughout the substrate on which such a layer as the upper conductive layer 16c is formed, such an inorganic insulating film (a thickness of approximately 500 nm) as an silicon oxide film is deposited by, for example, the plasma CVD to form the second interlayer insulating film 17.

After that, the gate insulating film 13, the first interlayer insulating film 15, and the second interlayer insulating film 17 are patterned, so that contact holes are formed in a monolayer film of the second interlayer insulating film 17, in a multilayer film of the first interlayer insulating film 15 and the second interlayer insulating film 17, and in a multilayer film of the gate insulating film 13, the first interlayer insulating film 15, and the second interlayer insulating film 17.

Moreover, in the folding portion B, a multilayer film of the base coat film 11, the gate insulating film 13, the first interlayer insulating film 15, and the second interlayer insulating film 17 is removed, so that the slit S is formed in the base coat film 11, the gate insulating film 13, the first interlayer insulating film 15, and the second interlayer insulating film 17 (a slit forming step).

Then, throughout the substrate in which the slit S is formed, for example, photosensitive polyimide resin is applied. After that, the applied film is prebaked, exposed to light, developed, and postbaked to form the filling resin film 8 to fill the slit S of the folding portion B (a filling resin film forming step).

After that, throughout the substrate on which the filling resin film 8 is formed, a titanium film (a thickness of approximately 30 nm), an aluminum film (a thickness of approximately 300 nm) and a titanium film (a thickness of approximately 50 nm) are sequentially deposited by, for example, sputtering. After that, the metal multilayer film of these metals is patterned to form such lines as the source lines 18f and the routed wires 18j (a routed wire forming step).

Finally, throughout the substrate on which, for example, the source lines 18f and the routed wires 18j are formed, a polyimide-based photosensitive resin film (a thickness of approximately 2 μm) is applied by, for example, spin-coating or slit-coating. The applied film is prebaked, exposed to light, developed, and postbaked to form the planarization resin film 19a. Here, when the planarization film 19a is formed, the lower resin layer 19b to be included in the first frame dam wall Wa, the lower resin layer 19c to be included in the second frame dam wall Wb, and the lower resin layer 19d to be included in the folding dam wall We are also formed simultaneously (a first folding dam wall forming step).

Through the above steps, the TFT layer 30a can be formed.

Organic-EL-Element Layer Forming Step (Light-Emitting-Element Layer Forming Step)

On the planarization film 19a of the TFT layer 30a formed at the TFT layer forming step, the first electrodes 31a, the edge cover 32a, the organic EL layers 33 (each including the hole-injection layer 1, the hole-transport layer 2, the organic light-emitting layer 3, the electron-transport layer 4, and the electron-injection layer 5), and the second electrode 34 are formed by a known technique to form the organic-EL-element layer 35. Here, in forming the edge cover 32a, a polyimide-based photosensitive resin film (a thickness of approximately 2 μm) is applied by, for example, spin-coating or slit-coating. After that, the applied film is prebaked, exposed to light, developed, and postbaked to form the edge cover 32a and the peripheral photo spacers 32b. In addition, the upper resin layer 32c to be included in the first frame dam wall Wa, the upper resin layer 32d to be included in the second frame dam wall Wb, and the upper resin layer 32e to be included in the folding dam wall We are formed (a second folding dam wall forming step).

Sealing Film Forming Step

First, on the surface of the substrate on which the organic-EL-element layer 35 is formed at the organic-EL-element-layer forming step, an inorganic insulating film such as, for example, a silicon nitride film, a silicon oxide film, or a silicon nitride oxide film is deposited to form the first inorganic sealing film 36 by the plasma CVD using a mask.

Next, on the surface of the substrate on which the first inorganic film 36 is formed, an organic resin material such as acrylic resin is discharged by, for example, ink-jet printing into an interior of each of the first frame dam wall Wa and the folding dam wall We to respectively form the organic sealing film 37a and the reinforcing resin film 37b.

Moreover, on the substrate on which the organic sealing film 37a is formed, an inorganic insulating film such as a silicon nitride film, a silicon oxide film, or a silicon nitride oxide film is deposited to form the second inorganic film 38 by the plasma CVD using a mask. Hence, the sealing film 40 is formed.

Finally, on the surface of the substrate on which the sealing film 40 is formed, a not-shown protective sheet is attached. After that, a laser beam is emitted on the glass substrate of the resin substrate layer 10 to remove the glass substrate from the bottom surface of the resin substrate layer 10. Furthermore, on the bottom surface of the resin substrate layer 10 with the glass substrate removed, a not-shown protective sheet is attached.

Through the above steps, the organic EL display device 50a of this embodiment can be manufactured. Note that this embodiment exemplifies the method of forming the reinforcing resin film 37b at the sealing film forming step, when the organic sealing film 37a is formed. Alternatively, the reinforcing resin film 37b may be formed at a mounting step following the sealing film forming step. The reinforcing resin film 37b may be formed of an organic resin material to be applied to an interior of the folding dam wall We using, for example, a dispenser apparatus.

As can be seen, as to the organic EL display device 50a and the method of manufacturing the organic EL display device 50a according to this embodiment, the folding dam wall We is provided around, and in contact with, the reinforcing resin film 37b on each of the routed wires 18j. When the reinforcing resin film 37b is formed by ink-jet printing at the sealing film forming step, such a feature can reduce excessive spreading of ink to form the reinforcing resin film 37b. This reduction in the excessive spreading of the ink reduces the width, of a portion of the frame region F along the folding portion B, in a direction perpendicular to the direction in which the folding portion B extends. Hence, the frame region of the organic EL display device 50a can be formed narrower even if the reinforcing resin film 37b is provided on the routed wires 18j in the folding portion B.

Moreover, as to the organic EL display device 50a and the method of manufacturing the organic EL display device 50a according to this embodiment, the folding dam wall We is provided to surround the reinforcing resin film 37b. Such a feature makes it possible to position a peripheral end portion of the reinforcing resin film 37b more precisely and control the thickness of the reinforcing resin film 37b more readily. As a result, the reinforcing resin film 37b can be formed highly flat. The flat reinforcing resin film 37b can reduce misalignment of the center of stress imposed when the organic EL display device 50a is folded at the folding portion B. Such a feature can keep a crack from opening on the routed wires 18j and the filling resin film 8, and reduce development of such a display defect as defective lines.

Furthermore, as to the organic EL display device 50a and the method of manufacturing the organic EL display device 50a according to this embodiment, the reinforcing resin film 37b is formed at the sealing film forming step. Such a feature can reduce contamination of the surface of the filling resin film 8 to be exposed from each of the routed wires 18j, compared with a case where the reinforcing resin film is formed at such a downstream process as, for example, the mounting step. Thanks to the reduction in contamination, the filling resin film 8 and the reinforcing resin film 37b adhere to each other more firmly. Such a feature can reduce delamination of the filling resin film 8 and the reinforcing resin film 37b from each other when the organic EL display device 50a is folded at the folding portion B. Here, at the sealing film forming step, the first inorganic sealing film 36 is formed by the plasma CVD, and the plasma treats the surface of the filling resin film 8 exposed from each of the routed wires 18j. Such a feature allows the filling resin film 8 and the reinforcing resin film 37b to adhere to each other more firmly.

In addition, as to the organic EL display device 50a and the method of manufacturing the organic EL display device 50a according to this embodiment, the reinforcing resin film 37b is formed at the sealing film forming step. Such a feature makes it possible to form the reinforcing resin film 37b on each of the routed wires 18j without an additional manufacturing step.

Moreover, as to the organic EL display device 50a and the method of manufacturing the organic EL display device 50a according to this embodiment, the reinforcing resin film 37b provided to the folding portion B is formed of the same material as that of the organic sealing film 37a, which is flexible and provided throughout the display region D. Such a feature can reduce stress to be imposed on the routed wires 18j when the organic EL display device 50a is folded at the folding portion B, making it possible to improve tolerance to cracks due to the fold.

### Second Embodiment

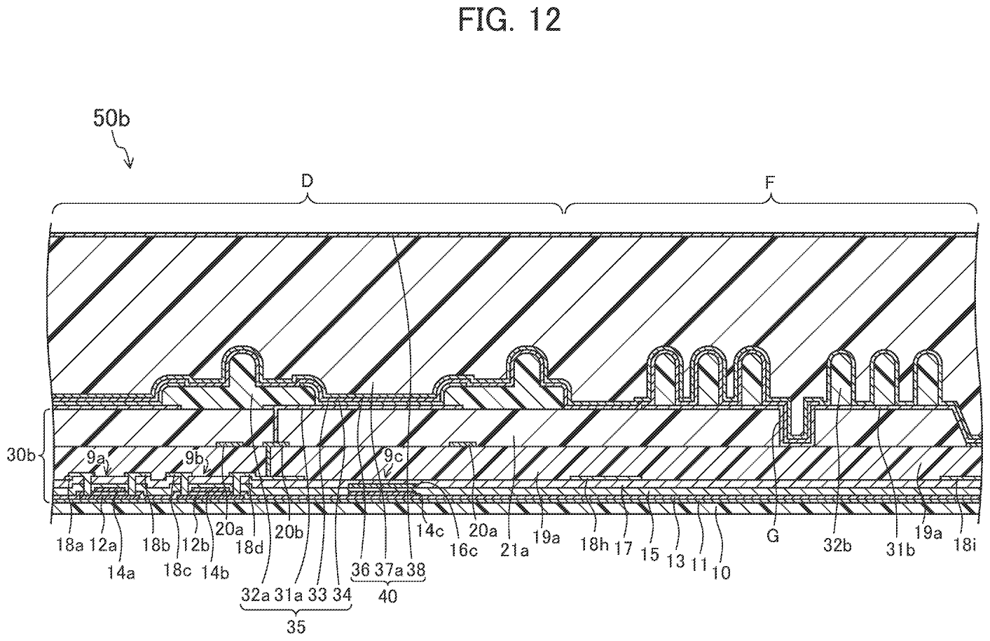

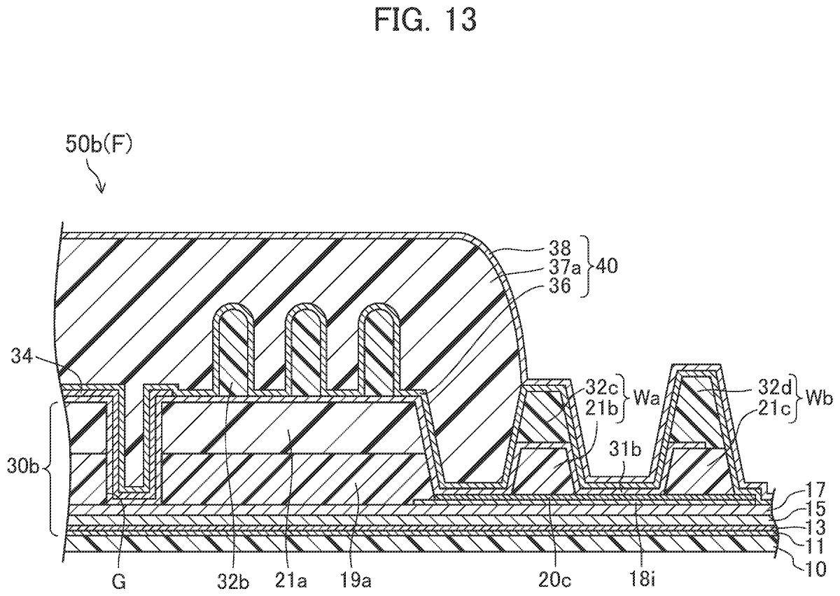

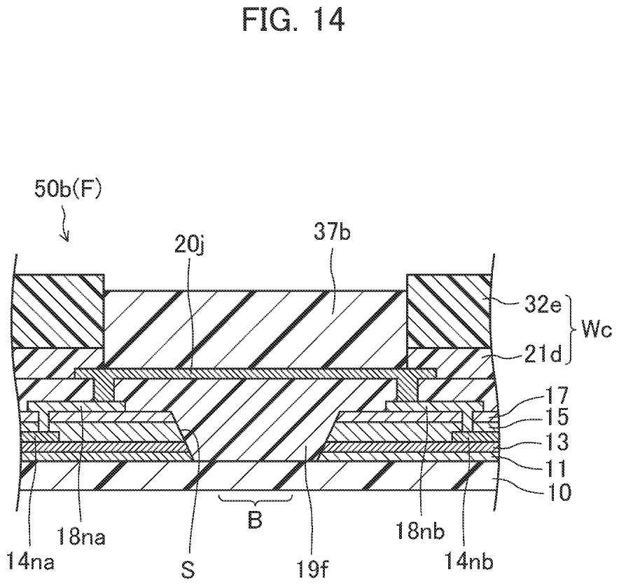

FIGS. 12 to 14 illustrate a second embodiment of a display device and a method of manufacturing the display device according to the present invention. Here, FIG. 12 is a cross-sectional view of an organic EL display device 50b according to this embodiment. FIG. 12 corresponds to FIG. 3. Moreover, FIGS. 13 and 14 are cross-sectional views of a frame region F of the organic EL display device 50b. FIGS. 13 and 14 correspond to FIGS. 6 and 7. Note that, in the embodiment below, like reference signs designate identical or corresponding components in FIGS. 1 to 11. These components will not be elaborated upon.

The first embodiment exemplifies the organic EL display device 50a including the first electrodes 31a provided on the planarization resin film 19a. This embodiment exemplifies the organic EL display device 50b including a second planarization resin film 21a provided on a first planarization resin film 19a that is substantially the same in configuration as the planarization resin film 19a. On the second planarization resin film 21a, the first electrodes 31a are provided.

Similar to the organic EL display device 50a of the first embodiment, the organic EL display device 50b includes: the display region D; and the frame region F provided around the display region D.

Moreover, as illustrated in FIGS. 12 and 13, the organic EL display device 50b includes: the resin substrate layer 10; a TFT layer 30b provided on the resin substrate layer 10; the organic-EL-element layer 35 provided on the TFT layer 30b; and the sealing film 40 provided to cover the organic-EL-element layer 35.

As illustrated in FIG. 12, the TFT layer 30b includes: the base coat film 11 provided on the resin substrate layer 10; the plurality of first TFTs 9a, the plurality of second TFTs 9b, and the plurality of capacitors 9c provided on the base coat film 11; the first planarization resin film 19a provided on each of the first TFTs 9a, each of the second TFTs 9b, and each of the capacitors 9c; a power source line 20a and a relay electrode 20b provided on the first planarization resin film 19a; and the second planarization resin film 21a provided on the power source line 20a and the relay electrode 20b. Here, the TFT layer 30b includes the plurality of gate lines 14 horizontally extending in parallel with one another, as seen in the TFT layer 30a included in the organic EL display device 50a according to the first embodiment. Moreover, the TFT layer 30b includes the plurality of source lines 18f horizontally extending in parallel with one another, as seen in the TFT layer 30a included in the organic EL display device 50a according to the first embodiment. Note that, the TFT layer 30b includes the power source line 20a provided in a grid, instead of the plurality of power source lines 18g of the TFT layer 30a included in the organic EL display device 50a according to the first embodiment. Moreover, in the TFT layer 30b, each of the sub-pixels P includes a first TFT 9a, a second TFT 9b, and a capacitor 9c, as seen in the TFT layer 30a included in the organic EL display device 50a according to the first embodiment.

In the organic-EL-element layer 35 according to this embodiment, as illustrated in FIG. 12, each of the first electrodes 31a is electrically connected to the drain electrode 18d of a corresponding one of the second TFTs 9b through a contact hole formed in the second planarization resin film 21a, the relay electrode 20b shaped into an island, and a contact hole formed in the first planarization resin film 19a.

Furthermore, similar to the organic EL display device 50a according to the first embodiment, the organic EL display device 50b illustrated in FIG. 13 includes in the frame region F: the first frame dam wall Wa shaped into a frame and provided outside the trench G to surround the display region D; and the second frame dam wall Wb shaped into a frame and provided around the first frame dam wall Wa.

The first frame dam wall Wa, as illustrated in FIG. 13, includes: a lower resin layer 21b formed of the same material as, and in the same layer as, the second planarization resin layer 21a is; and an upper resin layer 32c formed of the same material as, and in the same layer as, the edge cover 32a is, and provided above the lower resin layer 21b through the connection wire 31b.

The second frame dam wall Wb, as illustrated in FIG. 13, includes: a lower resin layer 21c formed of the same material as, and in the same layer as, the second planarization resin layer 21a is; and the upper resin layer 32d formed of the same material as, and in the same layer as, the edge cover 32a is, and provided above the lower resin layer 21c through the connection wire 31b.

Moreover, similar to the organic EL display device 50a of the first embodiment, the organic EL display device 50b includes the first frame wire 18h extending widely in a portion of the frame region F where the trench G is open. The first frame wire 18h has: opposing ends, toward the display region D, extending linearly behind the trench G along one side of the display region D; and opposing ends, across from the display region D, extending toward the terminal unit T. Note that, on the first frame wire 18h, a not-shown metal layer is stacked. The metal layer is formed of the same material as, and in the same layer as, the power source line 20a and the relay electrode 20b are. The metal layer can reduce wiring resistance of the first frame wire 18h.

Furthermore, similar to the organic EL display device 50a of the first embodiment, the organic EL display device 50b includes, in the frame region F, the second frame wire 18i shaped into a substantial C-shape and laid outside the trench G. The second frame wire 18i has opposing ends extending toward the terminal unit T. Here, on the second frame wire 18i, a metal layer 20c is stacked as illustrated in FIG. 13. The metal layer 20c is formed of the same material as, and in the same layer as, the power source line 20a and the relay electrode 20b are. The metal layer 20c can reduce wiring resistance of the second frame wire 18i.

In addition, similar to the organic EL display device 50a of the first embodiment, the organic EL display device 50b illustrated in FIG. 12 includes, in the frame region F, the plurality of peripheral photo spacers 32b each shaped into an island and provided to extend upwards at opposing edge portions of the trench G.

Moreover, as illustrated in FIG. 14, the organic EL display device 50b includes, in the folding portion B of the frame region F: a filling resin film 19f provided to fill the slit S formed in a multilayer film of the base coat film 11, the gate insulating film 13, the first interlayer insulating film 15, and the second interlayer insulating film 17; a plurality of routed wires 20j provided on the filling resin film 19f; and the reinforcing resin film 37b provided to cover an intermediate portion of each of the routed wires 20j.

The filling resin film 19f is formed of the same material as, and in the same layer as, the first planarization resin film 19a is.

The plurality of routed wires 20j are provided to extend in parallel with one another in a direction perpendicular to the direction in which the folding portion B extends. The plurality of routed wires 20j are formed of the same material as, and in the same layer as, the power source line 20a and the relay electrode 20b are. Here, as illustrated in FIG. 14, each of the routed wires 20j has opposing ends. One of the opposing ends is electrically connected to a first gate conductive layer 18na and another one of the opposing ends is electrically connected to a second gate conductive layer 18nb, through respective contact holes formed in the filling resin film 19f Note that the first source conductive layer 18na is formed of the same material as, and in the same layer as, the source electrodes 18a and 18c, the drain electrodes 18c and 18d, and the source lines 18f are. As illustrated in FIG. 14, the first source conductive layer 18na is electrically connected to the first gate conductive layer 14na through a contact hole formed in a multilayer film of the first interlayer insulating film 15 and the second interlayer insulating film 17. Moreover, the second source conductive layer 18nb is formed of the same material as, and in the same layer as, the source electrodes 18a and 18c, the drain electrodes 18c and 18d, and the source lines 18f are. As illustrated in FIG. 14, the second source conductive layer 18nb is electrically connected to the second gate conductive layer 14nb through a contact hole formed in a multilayer film of the first interlayer insulating film 15 and the second interlayer insulating film 17.

As seen in the organic EL display device 50a of the first embodiment, the reinforcing resin film 37b in FIG. 14 is surrounded with the folding dam wall We shaped into a single frame. Here, the folding dam wall We illustrated in FIG. 14 includes: a lower resin layer 21d formed of the same material as, and in the same layer as, the second planarization resin layer 21a is; and the upper resin layer 32e formed of the same material as, and in the same layer as, the edge cover 32a is, and stacked on the lower resin layer 21d. The folding dam wall We is in contact with the reinforcing resin layer 37b.

Note that this embodiment exemplifies the organic EL display device 50b including the reinforcing resin film 37b provided on each of the routed wires 20j. Similar to Modification 1 of the organic EL display device 50a of the first embodiment, a base resin film may be formed of the same material as, and in the same layer as, the second planarization resin film 21a is, and the base resin film may be provided between the reinforcing resin film 37b and each of the routed wires 20j.

Moreover, this embodiment exemplifies the organic EL display device 50b including the folding dam wall We shaped into a frame and provided around the reinforcing resin film 37b. Similar to Modification 2 of the organic EL display device 50a of the first embodiment, a pair of the short side portions of the folding dam wall We may be removed.

Similar to the organic EL display device 50a of the above first embodiment, the organic EL display device 50b is flexible, and allows, in each of the sub-pixels P, the light-emitting layer 3 of the organic EL layer 33 to appropriately emit light through the first TFT 9a and the second TFT 9b to display an image.

The organic EL display device 50b of this embodiment can be manufactured as follows.

Specifically, the slit forming step is carried out in the TFT layer forming step of the method of manufacturing the organic EL display device 50a of the first embodiment. After that, a titanium film (a thickness of approximately 30 nm), an aluminum film (a thickness of approximately 300 nm), and a titanium film (a thickness of approximately 50 nm) are sequentially deposited by, for example, sputtering throughout the substrate in which the slit S is formed. After that, the multilayer film of these metals is patterned to form, for example, the source lines 18f, the first source conductive layer 18na, and the second source conductive layer 18nb.

Then, throughout the substrate on which, for example, the source lines 18f are formed, a polyimide-based photosensitive resin film (a thickness of approximately 2 μm) is applied by, for example, spin-coating or slit-coating. The applied film is prebaked, exposed to light, developed, and postbaked to form the first planarization resin film 19a in the display region D, to form the filling resin film 19f in the folding portion B of the frame region F, and to form, for example, the lower resin layer 19c in the frame region F other than the folding portion B (a filling resin film forming step).

After that, throughout the substrate on which the first planarization resin film 19a is formed, a titanium film (a thickness of approximately 30 nm), an aluminum film (a thickness of approximately 300 nm) and a titanium film (a thickness of approximately 50 nm) are sequentially deposited by, for example, sputtering. After that, the metal multilayer film of these metals is patterned to form the power source line 20a, the relay electrode 20b, and the routed wires 20j (a routed wire forming step).

Moreover, throughout the substrate on which, for example, the power source line 20a is formed, a polyimide-based photosensitive resin film (a thickness of approximately 2 μm) is applied by, for example, spin-coating or slit-coating. The applied film is prebaked, exposed to light, developed, and postbaked to form the second planarization resin film 21a. Here, when the second planarization film 21a is formed, the lower resin layer 21b to be included in the first frame dam wall Wa, the lower resin layer 21c to be included in the second frame dam wall Wb, and the lower resin layer 21d to be included in the folding dam wall We are also formed simultaneously (a first folding dam wall forming step).

Through the above steps, the TFT layer 30b of this embodiment can be formed. Subsequently, the organic-EL-element-layer forming step and the sealing film forming step of the method of manufacturing the organic EL display device 50a according to the first embodiment are sequentially carried out, and the organic EL display device 50b of this embodiment can be manufactured. Note that, also in this embodiment, as seen in the first embodiment, the reinforcing resin film 37b may be formed at the mounting step following the sealing film forming step. The reinforcing resin film 37b may be formed of an organic resin material to be applied to an interior of the folding dam wall We using, for example, a dispenser apparatus.

As can be seen, as to the organic EL display device 50b and the method of manufacturing the organic EL display device 50b according to this embodiment, the folding dam wall We is provided around, and in contact with, the reinforcing resin film 37b on each of the routed wires 20j. When the reinforcing resin film 37b is formed by ink-jet printing at the sealing film forming step, such a feature can reduce excessive spreading of ink to form the reinforcing resin film 37b. This reduction in the excessive spreading of the ink reduces the width, of a portion of the frame region F along the folding portion B, in a direction perpendicular to the direction in which the folding portion B extends. Hence, the frame region of the organic EL display device 50b can be formed narrower even if the reinforcing resin film 37b is provided on the routed wires 20j in the folding portion B.

Moreover, as to the organic EL display device 50b and the method of manufacturing the organic EL display device 50b according to this embodiment, the folding dam wall We is provided to surround the reinforcing resin film 37b. Such a feature makes it possible to position a peripheral end portion of the reinforcing resin film 37b more precisely and control the thickness of the reinforcing resin film 37b more readily. As a result, the reinforcing resin film 37b can be formed highly flat. The flat reinforcing resin film 37b can reduce misalignment of the center of stress imposed when the organic EL display device 50b is folded at the folding portion B. Such a feature can keep a crack from opening on the routed wires 20j and the filling resin film 19f, and reduce development of such a display defect as defective lines.

Furthermore, as to the organic EL display device 50b and the method of manufacturing the organic EL display device 50b according to this embodiment, the reinforcing resin film 37b is formed at the sealing film forming step. Such a feature can reduce contamination of the surface of the filling resin film 19f to be exposed from each of the routed wires 20j, compared with a case where the reinforcing resin film is formed at such a downstream process as, for example, the mounting step. Thanks to the reduction in contamination, the filling resin film 19f and the reinforcing resin film 37b adhere to each other more firmly. Such a feature can reduce delamination of the filling resin film 19f and the reinforcing resin film 37b from each other when the organic EL display device 50b is folded at the folding portion B. Here, at the sealing film forming step, the first inorganic sealing film 36 is formed by the plasma CVD, and the plasma treats the surface of the filling resin film 19f exposed from each of the routed wires 18j. Such a feature allows the filling resin film 19f and the reinforcing resin film 37b to adhere to each other more firmly.

In addition, as to the organic EL display device 50b and the method of manufacturing the organic EL display device 50b according to this embodiment, the reinforcing resin film 37b is formed at the sealing film forming step. Such a feature makes it possible to form the reinforcing resin film 37b on each of the routed wires 20j without an additional manufacturing step.

Moreover, as to the organic EL display device 50b and the method of manufacturing the organic EL display device 50b according to this embodiment, the reinforcing resin film 37b provided to the folding portion B is formed of the same material as that of the organic sealing film 37a, which is flexible and provided throughout the display region D. Such a feature can reduce stress to be imposed on the routed wires 20j when the organic EL display device 50a is folded at the folding portion B, making it possible to improve tolerance to cracks due to the fold.

Furthermore, as to the organic EL display device 50b and the method of manufacturing the organic EL display device 50b according to this embodiment, the filling resin film 19f provided to fill the slit S of the folding portion B is formed of the same material as, and in the same layer as, the first planarization resin film 19a. Such a feature allows effective use of the organic resin material included in the filling resin film 19f.

### Other Embodiments

In the above embodiments, each organic EL layer is formed of a multilayer including such five layers as the hole-injection layer, the hole-transport layer, the light-emitting layer, the electron-transport layer, and the electron-injection layer. Alternatively, the organic EL layer may be formed of a multilayer including such three layers as a hole-injection and hole-transport layer, the light-emitting layer, and an electron-transport and electron-injection layer.

Moreover, in the organic EL display devices of the above embodiments described as examples, the first electrodes are anodes and the second electrode is a cathode. Alternatively, the present invention is applicable to an organic EL display device whose multilayered structure is inverted so that the first electrodes are cathodes and the second electrode is an anode.

Furthermore, in the organic EL display devices of the above embodiments described as examples, the electrodes of the TFTs connected to the first electrodes are drain electrodes. Alternatively, the present invention is applicable to an organic EL display device in which the electrodes of the TFTs connected to the first electrodes are referred to as source electrodes.

In addition, the display devices of the embodiments described as examples are organic EL display devices. Alternatively, the present invention is applicable to a display device including a plurality of light-emitting elements driven by a current. For example, the present invention is applicable to a display device including quantum-dot light emitting diodes (QLEDs); that is, light-emitting elements using layers containing quantum dots.

### INDUSTRIAL APPLICABILITY

As can be seen, the present invention is applicable to a flexible display device.

Reference Signs List

| | |
|---|---|
| B | Folding Portion |
| D | Display Region |
| F | Frame Region |
| L | Laser Beam |
| P | Sub-Pixel |
| S | Slit |
| T | Terminal Unit |
| Wa | First Frame Dam Wall |
| Wb | Second Frame Dam Wall |
| Wc | Folding Dam Wall |
| Wca, Wcc | First Dam Wall (Folding Dam Wall) |
| Wcb, Wcd | Second Dam Wall (Folding Dam Wall) |
| 8 | Filling Resin Film |
| 10 | Resin Substrate Layer |
| 11 | Base Coat Film (Inorganic |
| | Insulating Film) |
| 13 | Gate Insulating Film (Inorganic |
| | Insulating Film) |
| 15 | First Interlayer Insulating Film |
| | (Inorganic Insulating Film) |
| 17 | Second Interlayer Insulating Film |
| | (Inorganic Insulating Film) |
| 18f | Source Line (Display Wire) |
| 18j | Routed Wire |
| 19a | Planarization Resin Film (First |
| | Planarization Resin Film) |
| 19b, 19c, 19d, | Lower Resin Layer |
| 19da, 19db, 21b, | |
| 21c, 21d | |
| 19e | Base Resin Film |
| 21a | Second Planarization Resin Film |
| 30a, 30b | TFT Layer (Thin-Film Transistor Layer) |
| 31a | First Electrode |
| 32a | Edge Cover |
| 32c, 32d, 32e, | Upper Resin Layer |
| 32ea, 32eb | |
| 33 | Organic EL Layer (Light-Emitting |
| | Functional Layer) |
| 34 | Second Electrode |
| 35 | Organic-EL-Element Layer (Light- |
| | Emitting-Element Layer) |
| 36 | First Inorganic Sealing Film |
| 37a | Organic Sealing Film |
| 37b | Reinforcing Resin Film |
| 38 | Second Inorganic Sealing Film |
| 40 | Sealing Film |
| 50a, 50aa, 50ab, | Organic EL Display Device |
| 50ac, 50b | |

1. A display device, comprising:
a resin substrate layer;
a thin-film transistor layer provided on the resin substrate layer and including an inorganic insulating film;
a light-emitting-element layer provided on the thin-film transistor layer and including a plurality of first electrodes, a plurality of light-emitting functional layers, and a second electrode stacked on top of another in a stated order, each of the plurality of first electrodes and each of the plurality of light-emitting functional layers corresponding to one of a plurality of sub-pixels included in a display region, and the second electrode being provided in common among the plurality of sub-pixels;
a frame region provided around the display region;
a terminal unit provided to an end portion of the frame region;
a folding portion provided between the display region and the terminal unit to extend in a direction;
a slit included in the inorganic insulating film and provided to the folding portion to extend in the direction in which the folding portion extends;
a filling resin film provided to the folding portion to fill the slit;
a plurality of routed wires provided on the filling resin film to extend in parallel with one another in the direction in which the folding portion extends; and
a reinforcing resin film provided in the folding portion, the reinforcing resin film being shaped into a strip, being provided on the plurality of routed wires, and extending in the direction in which the folding portion extends,
wherein the reinforcing resin film is provided with a first dam wall toward the display region, the first dam wall being in contact with the reinforcing resin film and extending in the direction in which the folding portion extends, and
the reinforcing resin film is provided with a second dam wall toward the terminal unit, the second dam wall being in contact with the reinforcing resin film and extending in the direction in which the folding portion extends.

2. The display device according to claim 1,
wherein the first dam wall and the second dam wall have opposing ends connected together, and are shaped into a single frame to form a folding dam wall.

3. The display device according to claim 1,
wherein the display region is provided with a plurality of display wires extending in parallel with one another in the direction in which the folding portion extends,
the terminal unit includes a plurality of terminals arranged in the direction in which the folding portion extends, and
each of the plurality of routed wires is electrically connected: to a corresponding one of the plurality of display wires toward the display region; and to a corresponding one of the terminals toward the terminal unit.

4. The display device according to claim 1, further comprising
a sealing film provided to cover the light-emitting-element layer, and including a first inorganic sealing film, an organic sealing film, and a second inorganic sealing film stacked on top of another in a stated order,
wherein the filling resin film is formed of a same material as, and in a same layer as, the organic sealing film is.

5. The display device according to claim 4, further comprising:
a first frame dam wall provided in the frame region, surrounding the display region, and shaped into a frame to overlap with a peripheral end portion of the organic sealing film; and
a second frame dam wall shaped into a frame and provided around the first frame dam wall,
wherein the first dam wall and the second dam wall are formed of a same material as, and in a same layer as, the first frame dam wall and the second frame dam wall are.

6. The display device according to claim 5,
wherein the thin-film transistor layer includes a planarization resin film provided toward the light-emitting-element layer,
the light-emitting-element layer includes an edge cover provided, between the plurality of first electrodes and the plurality of light-emitting functional layers, in common among the plurality of sub-pixels to cover a peripheral end portion of each of the first electrodes,
each of the first frame dam wall, the second frame dam wall, the first dam wall, and the second dam wall includes: a lower resin layer formed of a same material as, and in a same layer as, the planarization resin layer is; and an upper resin layer stacked on the lower resin layer and formed of a same material as, and in a same layer as, the edge cover is.

7. The display device according to claim 6, further comprising
a base resin film provided between the plurality of routed wires and the reinforcing resin film, and formed of a same material as, and in a same layer as, the planarization resin film is.

8. The display device according to claim 7,
the base resin film is thinner than the planarization resin film.

9. The display device according to claim 5,
wherein, between the second frame dam wall and the first dam wall, the first inorganic sealing film is in contact with the inorganic insulating film.

10. The display device according to claim 1,
wherein each of the light-emitting functional layers is an organic electroluminescence layer.

11. A method of manufacturing a display device, comprising:
a thin-film transistor layer forming step of forming, on a resin substrate layer, a thin-film transistor layer including an inorganic insulating film;
a light-emitting-element layer forming step of forming, on the thin-film transistor layer, a light-emitting element layer including a plurality of first electrodes, a plurality of light-emitting functional layers, and a second electrode stacked on top of another in a stated order, each of the plurality of first electrodes and each of the plurality of light-emitting functional layers corresponding to one of a plurality of sub-pixels included in a display region, and the second electrode being provided in common among the plurality of sub-pixels; and
a sealing film forming step of forming, on the light-emitting element layer, a sealing film including a first inorganic sealing film, an organic sealing film, and a second inorganic sealing film stacked on top of another in a stated order,
the display device including: a frame region provided around the display region; a terminal unit provided to an end portion of the frame region; a folding portion provided between the display region and the terminal unit to extend in a direction; a first frame dam wall provided in the frame region, surrounding the display region, and shaped into a frame to overlap with a peripheral end portion of the organic sealing film; and a second frame dam wall shaped into a frame and provided around the first frame dam wall,
wherein the thin-film transistor layer forming step includes:
a slit forming step of forming a slit provided to the folding portion to extend in the direction in which the folding portion extends;
a filling resin film forming step of forming a filling resin film to fill the slit; and
a routed wire forming step of forming a plurality of routed wires provided on the filling resin film to extend in parallel with one another in the direction in which the folding portion extends,
the thin-film transistor layer forming step and the light-emitting-element layer forming step include a folding dam wall forming step of forming a folding dam wall shaped into a rectangular frame having a pair of long sides extending in the direction in which the folding portion extends, the long sides sandwiching the folding portion, and
when the organic sealing film is formed in an interior of the first frame dam wall, the sealing film forming step forms a reinforcing resin film on the plurality of routed wires behind the folding dam wall, the reinforcing resin film being shaped into a strip.

12. The method according to claim 11,
wherein the organic sealing film and the reinforcing resin film are formed of a same material by ink-jet printing.

13. The method according to claim 11, further comprising
a laser cutting step after the sealing film forming step, the laser cutting step emitting a laser beam to, and cutting, the resin substrate layer, and removing a pair of short side portions of the folding dam wall, to form: a first dam wall provided in contact with the reinforcing resin film toward the display region, and extending in the direction in which the folding portion extends; and a second dam wall provided in contact with the reinforcing resin film toward the terminal unit, and extending in the direction in which the folding portion extends.

14. The display device according to claim 11,
wherein each of the light-emitting functional layers is an organic electroluminescence layer.
